(19) United States
(12) Patent Application Publication
(10) Pub. No.: US 2018/0006608 A1
(43) Pub. Date: Jan. 4, 2018

(54) BIAS CIRCUIT

(71) Applicant: Murata Manufacturing Co., Ltd., Kyoto (JP)

(72) Inventors: Satoshi TANAKA, Kyoto (JP); Tetsuaki ADACHI, Kyoto (JP); Kazuo WATANABE, Kyoto (JP); Masahito NUMANAMI, Kyoto (JP); Yasuhisa YAMAMOTO, Kyoto (JP)

(21) Appl. No.: 15/480,584

(22) Filed: Apr. 6, 2017

(30) Foreign Application Priority Data
Jul. 1, 2016 (JP) 2016- 131719

(51) Int. Cl. H03F 1/02; H03F 3/193

(52) U.S. Cl. CPC H03F 1/0205; H03F 3/193; H03F 2200/451; H03F 2200/411; H03F 2200/318; H03F 2200/222; H03F 2200/555; H03F 2200/387

(57) ABSTRACT

Provided is a bias circuit that supplies a first bias current or voltage to an amplifier that amplifies a radio frequency signal. The bias circuit includes: an FET that has a power supply voltage supplied to a drain thereof and that outputs the first bias current or voltage from a source thereof; a first bipolar transistor that has a collector thereof connected to a gate of the FET, that has a base thereof connected to the source of the FET, that has a common emitter and that has a constant current supplied to the collector thereof; and a first capacitor that has one end thereof connected to the collector of the first bipolar transistor and that suppresses variations in a collector voltage of the first bipolar transistor.

This application claims priority from Japanese Patent Application No. 2016-131719 filed on Jul. 1, 2016. The content of this application is incorporated herein by reference in its entirety.

### BACKGROUND

The present disclosure relates to bias circuits. A power amplification circuit is used in a mobile communication device such as a cellular phone in order to amplify the power of a radio frequency (RF) signal to be transmitted to a base station. A bias circuit is used in such a power amplification circuit. The bias circuit is for supplying a bias voltage or bias current to an amplifier. For example, US Patent Application Publication No. 2015/0349715 discloses a bias circuit that includes a transistor Fb1 that supplies a bias current to a transistor Q1 and a transistor Q1r that adjusts the gate voltage of the transistor Fb1 in accordance with a reference current such that a bias current of a constant size is output.

In the configuration disclosed in US Patent Application Publication No. 2015/0349715, a voltage that corresponds to the amplitude of an RF signal is applied to the output terminal of a current generating circuit that generates the reference current and therefore the size of the reference current may vary when there are large variations in the amplitude of the RF signal. Consequently, the accuracy of the bias current adjusting function performed by the transistor Q1r is reduced and the bias current may be insufficient at the time of large signal input.

### BRIEF SUMMARY

The present disclosure was made in light of the above-described circumstances and the present disclosure provides a bias circuit that stably supplies a bias current regardless of the signal level of an input signal.

According to an embodiment of the present disclosure, a bias circuit is provided that supplies a first bias current or voltage to an amplifier that amplifies a radio frequency signal. The bias circuit includes: an FET that has a power supply voltage supplied to a drain thereof and that outputs the first bias current or voltage from a source thereof; a first bipolar transistor that has a collector thereof connected to a gate of the FET, that has a base thereof connected to the source of the FET, that has a common emitter and that has a constant current supplied to the collector thereof; and a first capacitor that has one end thereof connected to the collector of the first bipolar transistor and that suppresses variations in a collector voltage of the first bipolar transistor.

According to an embodiment of the present disclosure, a bias circuit is provided that stably supplies a bias current regardless of the signal level of an input signal.

Other features, elements, characteristics and advantages of the present disclosure will become more apparent from the following detailed description of embodiments of the present disclosure with reference to the attached drawings.

### BRIEF DESCRIPTION OF THE SEVERAL VIEWS OF THE DRAWINGS

FIG. 1 illustrates an example configuration of a power amplification circuit according to a first embodiment of the present disclosure;

FIG. 2 illustrates an example configuration of the power amplification circuit according to the first embodiment of the present disclosure;

FIG. 3 illustrates an example configuration of a power amplification circuit according to a modification of the first embodiment of the present disclosure;

FIG. 4 illustrates an example configuration of a power amplification circuit according to another modification of the first embodiment of the present disclosure;

FIG. 5 illustrates an example configuration of a power amplification circuit according to a second embodiment of the present disclosure;

FIG. 6 illustrates an example configuration of a power amplification circuit according to a modification of the second embodiment of the present disclosure; and

FIG. 7 illustrates an example configuration of a power amplification circuit according to another modification of the second embodiment of the present disclosure.

### DETAILED DESCRIPTION

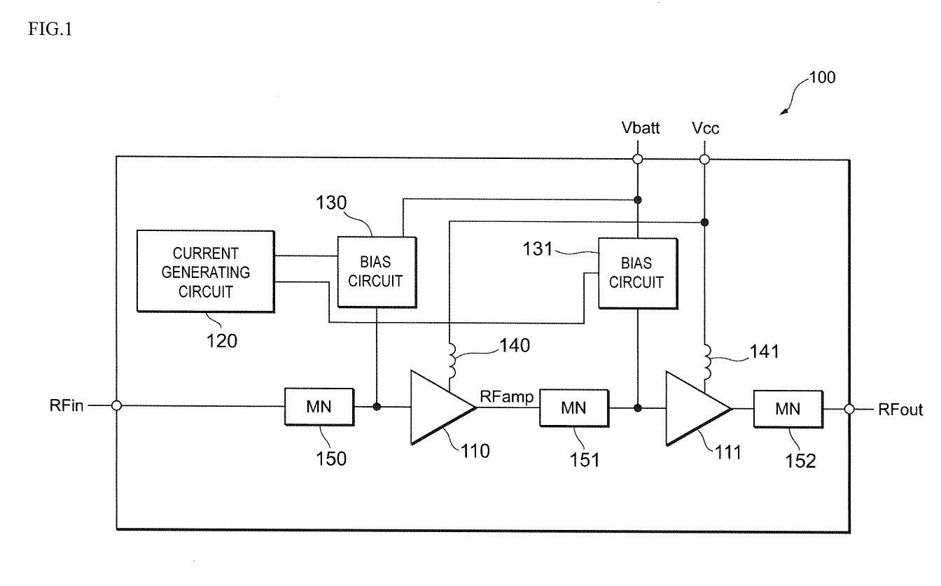

Hereafter, embodiments of the present disclosure will be described while referring to the drawings. FIG. 1 illustrates a configuration of a power amplification circuit 100 according to a first embodiment of the present disclosure. The power amplification circuit 100 amplifies an input radio frequency signal and outputs an output signal in a mobile communication device such as a cellular phone, for example. The frequency of an input signal RFin is around several GHz, for example.

As illustrated in FIG. 1, the power amplification circuit 100 includes amplifiers 110 and 111, a current generating circuit 120, bias circuits 130 and 131, inductors 140 and 141 and matching networks 150, 151 and 152.

The amplifiers 110 and 111 form a two-stage amplifier. The amplifier 110 (drive stage) amplifies the input signal RFin input thereto and outputs an amplified signal RFamp. The amplifier 111 (power stage) amplifies the amplified signal RFamp output from the amplifier 110 and outputs an output signal RFout. A prescribed power supply voltage Vcc is supplied to the amplifiers 110 and 111 via the inductors 140 and 141, respectively. In addition, a bias current or bias voltage is supplied from the bias circuit 130 to the amplifier 110 and a bias current or bias voltage is supplied from the bias circuit 131 to the amplifier 111. The number of stages of the amplifier is not limited to two and may be one or three or more. The configurations of the amplifiers 110 and 111 will be described in detail later.

The current generating circuit 120 generates a reference current (constant current) of a prescribed size and supplies the generated reference current to the bias circuits 130 and 131. The current generating circuit 120 is formed of a current source and a current-mirror-connected MOSFET, for example.

The bias circuits 130 and 131 respectively supply bias currents to the amplifiers 110 and 111 in accordance with the reference current supplied from the current generating circuit 120. The configurations of the bias circuits 130 and 131 will be described in detail later.

The inductors 140 and 141 are connected between a power supply voltage terminal and the amplifiers 110 and 111 and suppress coupling of a high-frequency signal with a power supply circuit.

The matching networks (MN's) 150, 151 and 152 are respectively provided before and after the amplifiers 110 and 111 and match the impedances between the amplifiers. The matching networks 150, 151 and 152 are formed using capacitors and inductors, for example.

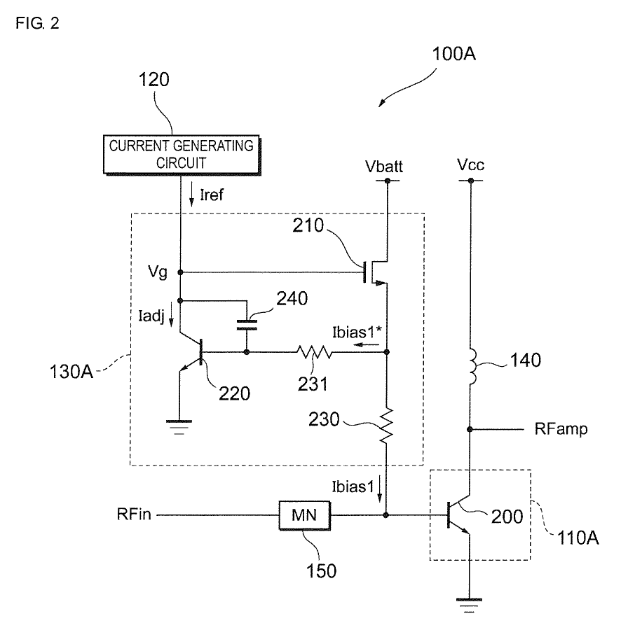

FIG. 2 illustrates an example configuration of the power amplification circuit 100 according to the first embodiment of the present disclosure (power amplification circuit 100A). In the power amplification circuit 100A, specific example configurations of the amplifier 110 and the bias circuit 130 illustrated in FIG. 1 (amplifier 110A and bias circuit 130A) are illustrated. Although the bias circuit 130 that is applied to the amplifier 110 (drive stage) is described as an example in FIGS. 2 to 7, the configuration of this bias circuit may be applied to an amplifier of any stage.

The amplifier 110A includes a transistor 200. In this embodiment, the transistor 200 is a bipolar transistor such as a heterojunction bipolar transistor (HBT). A metal-oxide-semiconductor field effect transistor (MOSFET) may be used as the amplification transistor instead of a bipolar transistor.

The power supply voltage Vcc is supplied to the collector of the transistor 200 via the inductor 140, the input signal RFin is supplied to the base of transistor 200 via the matching network 150 and the transistor 200 has a common emitter. In addition, a bias current Ibias1 (first bias current) is supplied to the base of the transistor 200 from the bias circuit 130A. Thus, the amplified signal RFamp, which is obtained by amplifying the input signal RFin, is output from the collector of the transistor 200.

The bias circuit 130A includes a MOSFET 210, a transistor 220, resistance elements 230 and 231 and a capacitor 240. The bias circuit 130A generates a bias current having a size that corresponds to a reference current Iref output from the current generating circuit 120 and supplies the generated bias current to the amplifier 110A.

A power supply voltage Vbatt is supplied to the drain of the MOSFET 210, the gate of the MOSFET 210 is connected to an output terminal of the current generating circuit 120 and the collector of the transistor 220, and the source of the MOSFET 210 is connected to one end of each of the resistance elements 230 and 231. A voltage that corresponds to a current Iadj, which flows through the transistor 220, is supplied to the gate of the MOSFET 210. Thus, a current corresponding to the gate-source voltage of the MOSFET 210 is output from the source of the MOSFET 210. This current is divided into the bias current Ibias1, which is supplied to the base of the transistor 200, and a bias current Ibias1*, which is supplied to the base of the transistor 220, in accordance with the resistance values of the resistance elements 230 and 231.

The transistor 220 (first bipolar transistor) is formed of a bipolar transistor in this embodiment. The reference current Iref is supplied to the collector of the transistor 220, the base of the transistor 220 is connected to another end of the resistance element 231 and the transistor 200 has a common emitter. The bias current Ibias1* is supplied to the base of the transistor 220 via the resistance element 231.

The one end of the resistance element 230 is connected to the source of the MOSFET 210 and the other end of the resistance element 230 is connected to the base of the transistor 200. One end of the resistance element 231 is connected to the source of the MOSFET 210 and the other end of the resistance element 231 is connected to the base of the transistor 220. The resistance elements 230 and 231 adjust the allocation of the bias currents Ibias1 and Ibias1*.

One end of the capacitor 240 (first capacitor) is connected to the collector of the transistor 220 and the other end of the capacitor 240 is connected to the base of the transistor 220. Before explaining the function of the capacitor 240, a configuration that does not include the capacitor 240 will be described.

The bias currents Ibias1 and Ibias1* are supplied using the same configuration to the transistor 200 and the transistor 220 by the MOSFET 210 in the bias circuit 130A. Therefore, the current Iadj, which is proportional to a current that flows through the transistor 200, flows to the transistor 220 in accordance with the element size of the transistor 220.

In addition, a gate voltage Vg of the MOSFET 210 is subjected to negative feedback such that the current Iadj and the reference current Iref, which is supplied from the current generating circuit 120, come to have approximately the same size. For example, in the case where the size of the bias current Ibias1 increases, the size of the current Iadj that flows to the transistor 220 increases so as to be proportional to the base current or collector current that flows through the transistor 200. However, since the transistor 220 operates such that a current having the same size as the reference current Iref flows thereto, the current that flows to the transistor 220 is limited by the reference current Iref. Thus, an increase in the collector voltage of the transistor 220 (=gate voltage Vg of MOSFET 210) is suppressed and therefore the size of the current that flows through the MOSFET 210 is stable. With the above-described configuration, even when the bias current Ibias1 varies with the supply of the input signal RFin and the bias current Ibias1* also varies along with this variation, negative feedback is performed such that the bias current Ibias1 has a constant size that corresponds to the reference current Iref.

On the other hand, when the input signal RFin is a large signal, the collector voltage of the transistor 220 varies with the amplitude of the RF signal that leaks to the base of the transistor 220. As a result, variations in the amplitude of the RF signal have an effect on the output terminal of the current generating circuit 120 via the transistor 220 and the reference current Iref output by the current generating circuit 120 may vary. Specifically, for example, the current generating circuit 120 may be formed of a current source and a current-mirror-connected MOSFET and the reference current Iref may be output from the drain of the MOSFET. In this case, the drain-source voltage of the MOSFET may decrease as the collector voltage of the transistor 220 increases and a reference current of a desired size may not be output.

However, the bias circuit 130A is provided with the capacitor 240 between the base and the collector of the transistor 220. Here, Cbc represents the capacitance value of the capacitor 240, gm represents voltage gain of the transistor 220, and Z represents the impedance seen when looking toward the current generating circuit 120 from collector of the transistor 220. The capacitor 240 has a configuration equivalent to a capacitor that AC grounds the base of the transistor 220 with a capacitance value that is (1+gm×Z)×Cbc due to the mirror effect seen from the base of the transistor 220. Therefore, variations in the base voltage of the transistor 220 that occur with variations in the amplitude of the RF signal are suppressed by this capacitor. Thus, variations in the collector voltage of the transistor 220 are suppressed and therefore the reference current Iref is stably supplied. Therefore, a bias current Ibias1 of a prescribed size is supplied even at the time of large signal input.

With the above-described configuration, the bias circuit 130A is able to stably supply a bias current regardless of the signal level of the input signal RFin. Since the mirror effect is obtained, a capacitor having a comparatively small capacitance value can be used as the capacitor 240. Thus, the capacitor 240 can be provided while suppressing an increase in the circuit area of the bias circuit. For example, the capacitance value of the capacitor 240 can be larger than the value of a parasitic capacitance between the gate and source of the MOSFET 210 and be a capacitance value of such a size that the transistor 220 suitably operates (for example, around 2 pF to 6 pF).

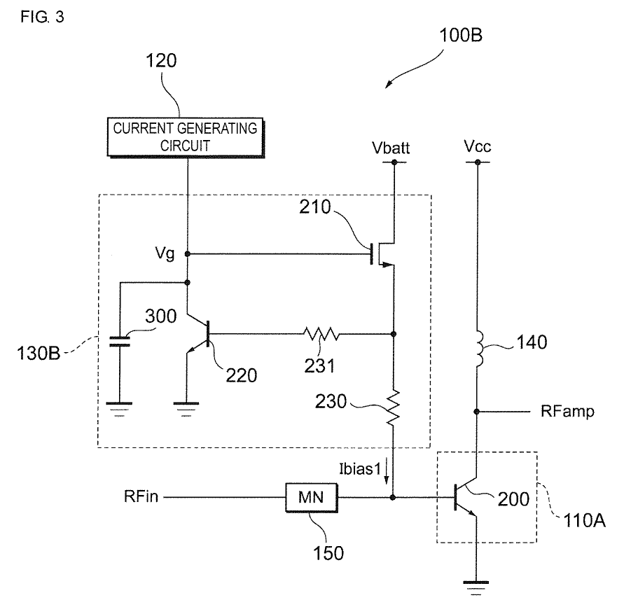

FIG. 3 illustrates an example configuration of a power amplification circuit 100 according to a modification of the first embodiment of the present disclosure (power amplification circuit 100B). The power amplification circuit 100B includes a bias circuit 130B instead of the bias circuit 130A illustrated in FIG. 2. Compared to the bias circuit 130A illustrated in FIG. 2, the bias circuit 130B includes a capacitor 300 instead of the capacitor 240.

One end of the capacitor 300 is connected to the collector of the transistor 220 and the other end of the capacitor 300 is grounded. In other words, the capacitor 300 AC grounds the collector of the transistor 220. Thus, variations in the collector voltage of the transistor 220 caused by variations in the amplitude of the RF signal can be suppressed. With this configuration as well, similarly to as in the power amplification circuit 100A, variations in the reference current Iref are suppressed and the bias current Ibias1 is stably supplied even at the time of large signal input.

Since the above-described mirror effect is not obtained, the capacitor 300 of the bias circuit 130B needs to have a larger capacitance value than the capacitor 240 of the bias circuit 130A. On the other hand, the capacitor 300 directly AC grounds the collector rather than the base of the transistor 220. Therefore, in contrast to the bias circuit 130A illustrated in FIG. 2, the bias circuit 130B can suppress variations in the collector voltage of the transistor 220 (that is, the gate voltage Vg of the MOSFET 210) without necessarily affecting the negative feedback realized by the transistor 220. Thus, the bias circuit 130B can suppress variations in the reference current Iref caused by variations in the amplitude of the input signal RFin while maintaining the function of adjusting the bias current Ibias1 through negative feedback.

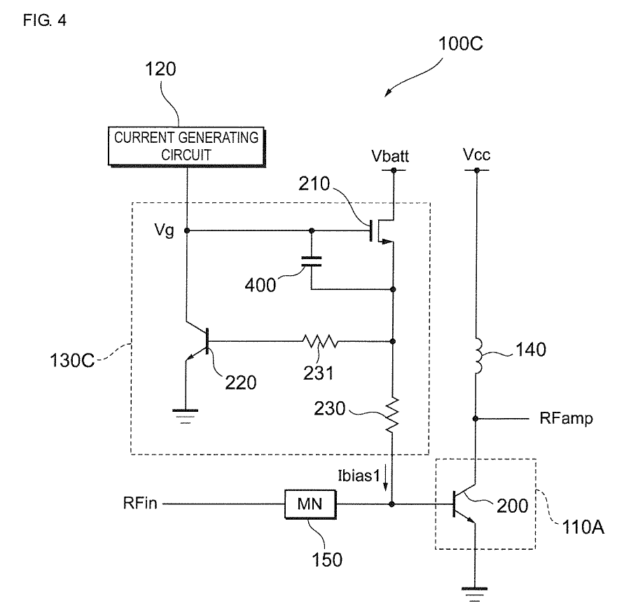

FIG. 4 illustrates an example configuration of a power amplification circuit 100 according to another modification of the first embodiment of the present disclosure (power amplification circuit 100C). The power amplification circuit 100C includes a bias circuit 130C instead of the bias circuit 130A illustrated in FIG. 2. Compared to the bias circuit 130A illustrated in FIG. 2, the bias circuit 130C includes a capacitor 400 instead of the capacitor 240.

One end of the capacitor 400 is connected to the gate of the MOSFET 210 and the other end of the capacitor 400 is connected to the source of the MOSFET 210. Similarly to the capacitor 300 illustrated in FIG. 3, the capacitor 400 suppresses variations in the collector voltage of the transistor 220 (that is, the gate voltage Vg of the MOSFET 210), which are caused by variations in the amplitude of the input signal RFin.

With this configuration as well, similarly to as in the bias circuits 130A and 130B, variations in the collector voltage of the transistor 220 are suppressed and therefore variations in the reference current Iref are also suppressed. Therefore, the bias current Ibias1 is stably supplied even at the time of large signal input.

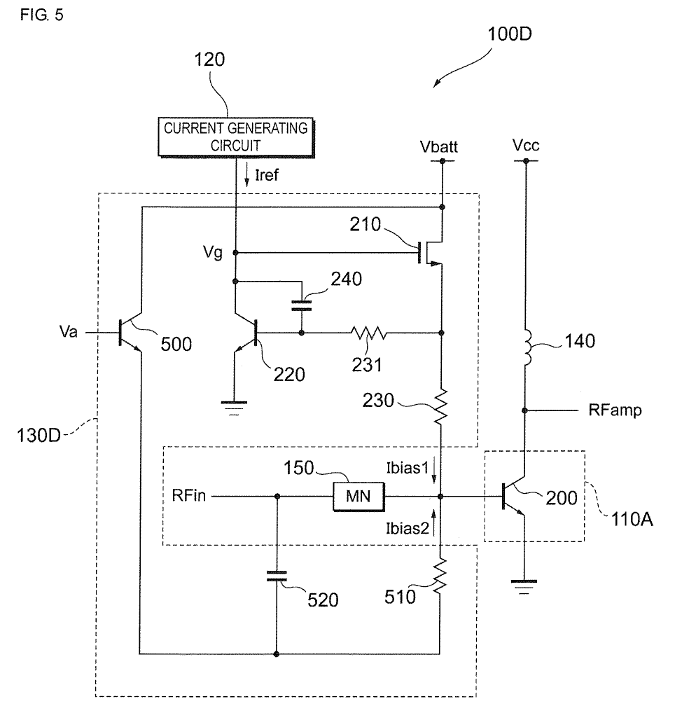

FIG. 5 illustrates an example configuration of a power amplification circuit 100 according to a second embodiment of the present disclosure (power amplification circuit 100D). The power amplification circuit 100D includes a bias circuit 130D instead of the bias circuit 130A illustrated in FIG. 2. Compared with the bias circuit 130A illustrated in FIG. 2, the bias circuit 130D further includes a transistor 500, a resistance element 510 and a capacitor 520. The transistor 500, the resistance element 510 and the capacitor 520 form an additional path along which a bias current of the transistor 200 is supplied and that is different from the bias current supply path that includes the MOSFET 210.

The transistor 500 (second bipolar transistor) is formed of a bipolar transistor in this embodiment. The transistor 500 forms an emitter-follower circuit in which the power supply voltage Vbatt is supplied to the collector of the transistor 500, a control voltage Va is supplied to the base of the transistor 500 and the emitter of the transistor 500 is connected to one end of each of the resistance element 510 and the capacitor 520. The transistor 500 outputs a bias current Ibias2 (second bias current) from the emitter thereof in accordance with the control voltage Va and supplies the bias current Ibias2 to the base of the transistor 200 via the resistance element 510.

One end of the resistance element 510 is connected to the emitter of the transistor 500 and the other end of the resistance element 510 is connected to the base of the transistor 200. The resistance element 510 adjusts the bias current Ibias2 supplied to the transistor 200.

One end of the capacitor 520 (second capacitor) is connected to the emitter of the transistor 500 and the input signal RFin is supplied to the other end of the capacitor 520. By supplying the input signal RFin to the emitter of the transistor 500 via the capacitor 520, the emitter voltage of the transistor 500 can be made to vary in accordance with the amplitude of the input signal RFin. Thus, when the emitter voltage of the transistor 500 falls in accordance with the amplitude of the input signal at the time of a large input signal RFin, the transistor 500 turns on and an additional bias current Ibias2 is supplied to the base of the transistor 200.

In the bias circuit 130D, in addition to the bias current Ibias1, the bias current Ibias2 is also supplied to the base of the transistor 200 via the supply path including the transistor 500. Specifically, for example, the control voltage Va can be adjusted such that the transistor 500 is off at the time of a small input signal RFin and the transistor 500 is on at the time of a large input signal RFin. Thus, the bias current Ibias2 is additionally supplied at the time of a large input signal RFin and the total bias current supplied to the base of the transistor 200 is increased. Therefore, the occurrence of an insufficient bias current at the time of large signal input is suppressed.

With this configuration as well, similarly to as in the power amplification circuit 100A, variations in the collector voltage of the transistor 220 are suppressed and therefore variations in the reference current Iref are also suppressed. Therefore, the bias current can be stably supplied even at the time of large signal input. In addition, compared with the power amplification circuit 100A, the power amplification circuit 100D suppresses the occurrence'of an insufficient bias current at the time of large signal input.

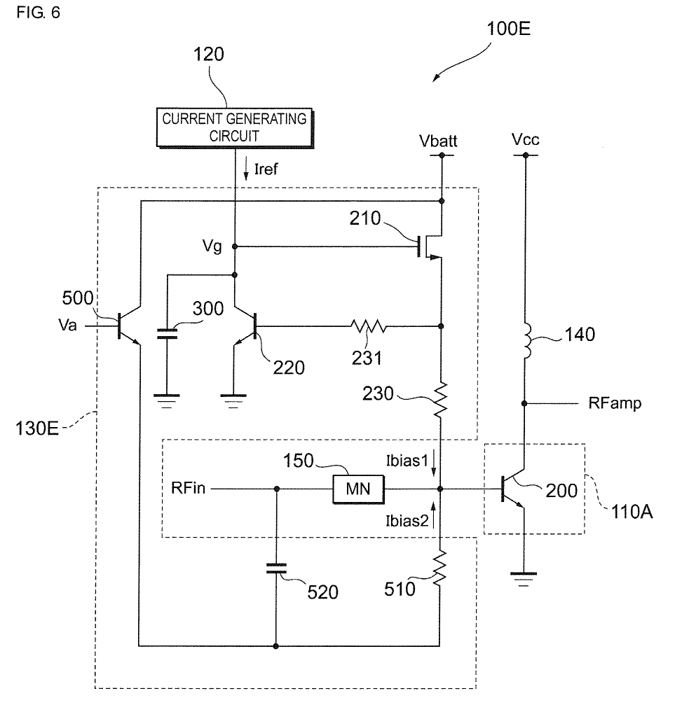

FIG. 6 illustrates an example configuration of a power amplification circuit 100 according to a modification of the second embodiment of the present disclosure (power amplification circuit 100E). The power amplification circuit 100E includes a bias circuit 130E instead of the bias circuit 130D illustrated in FIG. 5. Compared to the bias circuit 130D illustrated in FIG. 5, the bias circuit 130E includes the capacitor 300 instead of the capacitor 240.

The capacitor 300 is the same as the capacitor 300 illustrated in FIG. 3 and therefore detailed description thereof is omitted. With this configuration as well, the same effect as with the power amplification circuit 100D can be obtained. In addition, the bias circuit 130E can suppress variations in the reference current Iref caused by variations in the amplitude of the input signal RFin while maintaining the function of adjusting the bias current Ibias1 through the negative feedback realized by the transistor 220.

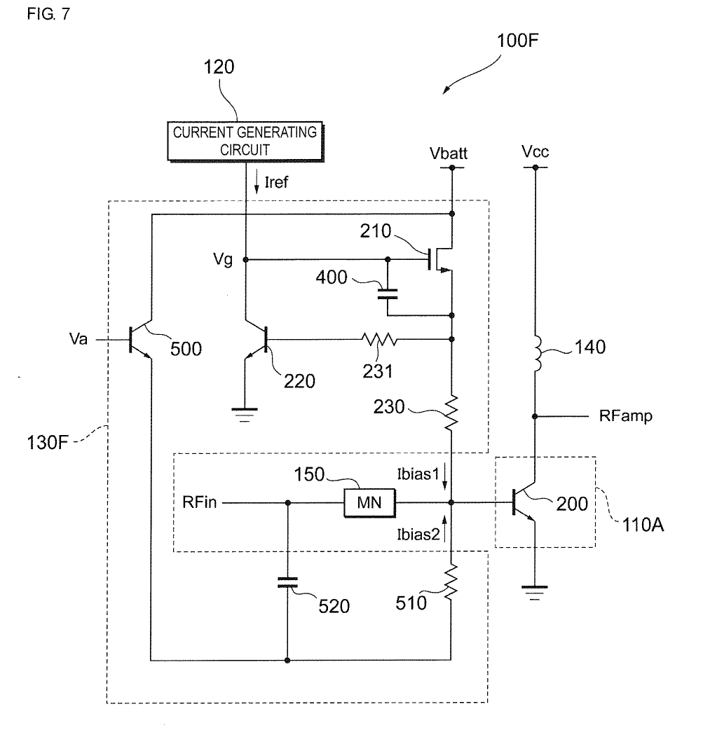

FIG. 7 illustrates an example configuration of a power amplification circuit 100 according to another modification of the second embodiment of the present disclosure (power amplification circuit 100F). The power amplification circuit 100F includes a bias circuit 130F instead of the bias circuit 130D illustrated in FIG. 5. Compared to the bias circuit 130D illustrated in FIG. 5, the bias circuit 130F includes the capacitor 400 instead of the capacitor 240.

The capacitor 400 is the same as the capacitor 400 illustrated in FIG. 4 and therefore detailed description thereof is omitted. With this configuration as well, the same effect as with the power amplification circuits 100D and 100E can be obtained.

Exemplary embodiments of the present disclosure have been described above. The power amplification circuits 100A to 100F each include: the MOSFET 210 that outputs the first bias current or voltage from the source thereof; the transistor 220 that has the collector thereof connected to the gate of the MOSFET 210, the base thereof connected to the source of the MOSFET 210, that has a common emitter and that has the reference current Iref supplied to the collector thereof; and a capacitor that has one end thereof connected to the collector of the transistor 220. Thus, variations in the base voltage and the collector voltage of the transistor 220 that occur with variations in the amplitude of the RF signal are suppressed. Therefore, the size of the reference current Iref is stable even at the time of large signal input and a bias current is stably supplied regardless of the signal level of the input signal.

In addition, in the power amplification circuit 100A, the other end of the capacitor 240 is connected to the base of the transistor 220. As a result, a mirror effect is obtained, and therefore the capacitor 240 can have a comparatively small capacitance value. Therefore, the capacitor 240 can be provided while suppressing an increase in the circuit area of the bias circuit 130A.

In addition, in the power amplification circuit 100B, the other end of the capacitor 300 is grounded. Thus, variations in the collector voltage of the transistor 220 can be suppressed without necessarily affecting the negative feedback realized by the transistor 220. Therefore, variations in the reference current Iref can be suppressed while retaining the function of adjusting the bias current Ibias1.

In addition, as illustrated in FIG. 4, the other end of the capacitor 400 may be connected to the source of the MOSFET 210. The capacitor 400 is not limited to this configuration.

In addition, the power amplification circuits 100D to 100F each include: the transistor 500 that has the power supply voltage Vbatt supplied to the collector thereof, that has the control voltage Va supplied to the base thereof and that supplies the bias current Ibias2 to the transistor 200 from the emitter thereof; and the capacitor 520 that has one end thereof connected to the emitter of the transistor 500 and has the input signal RFin supplied to the other end thereof. Thus, since the bias current Ibias2 is additionally supplied at the time of a large input signal RFin, the total bias current supplied to the base of the transistor 200 is increased. Therefore, the occurrence of an insufficient bias current at the time of large signal input is suppressed.

The bias circuits 130A to 130F each have a configuration that includes one capacitor from among the capacitors 240, 300 and 400, but the bias circuit 130 is not limited to this configuration and may instead include a plurality of capacitors from among the capacitors 240, 300 and 400.

The purpose of the embodiments described above is to enable easy understanding of the present disclosure and the embodiments are not to be interpreted as limiting the present disclosure. The present disclosure can be changed or improved without departing from the gist of the disclosure and equivalents to the present disclosure are also included in the present disclosure. In other words, appropriate design changes made to the embodiments by one skilled in the art are included in the scope of the present disclosure so long as the changes have the characteristics of the present disclosure. For example, the elements included in the embodiments and the arrangements, materials, conditions, shapes, sizes and so forth of the elements are not limited to those exemplified in the embodiments and can be appropriately changed. In addition, the elements included in the embodiments can be combined as much as technically possible and such combined elements are also included in the scope of the present disclosure so long as the combined elements have the characteristics of the present disclosure.

While specific embodiments of the disclosure have been described above, it is to be understood that variations and modifications will be apparent to those skilled in the art without departing from the scope and spirit of the disclosure. The scope of the invention, therefore, is to be determined solely by the following claims.

What is claimed is:

1. A bias circuit that supplies a first bias current or voltage to an amplifier that amplifies a radio frequency signal, the bias circuit comprising:
a field-effect transistor (FET), wherein a power supply voltage is supplied to a drain of the FET and a source of the FET outputs the first bias current or voltage;
a first bipolar transistor, wherein a collector of the first bipolar transistor is connected to a gate of the FET, a base of the first bipolar transistor is connected to the source of the FET, the first bipolar transistor has a common emitter, and a constant current is supplied to the collector of the first bipolar transistor; and
a first capacitor, wherein a first end of the first capacitor is connected to the collector of the first bipolar transistor and the first capacitor suppresses variations in a collector voltage of the first bipolar transistor.

2. The bias circuit according to claim 1,
wherein a second end of the first capacitor is connected to the base of the first bipolar transistor.

3. The bias circuit according to claim 1,
wherein a second end of the first capacitor is grounded.

4. The bias circuit according to claim 1,
wherein a second end of the first capacitor is connected to the source of the FET.

5. The bias circuit according to claim 1, further comprising:
a second bipolar transistor, wherein a power supply voltage is supplied to a collector of the second bipolar transistor, a control voltage is supplied to a base of the second bipolar transistor, and a second bias current or voltage is supplied from an emitter of the second bipolar transistor to the amplifier; and
a second capacitor,
wherein a first end of the second capacitor is connected to the emitter of the second bipolar transistor and the radio frequency signal is supplied to a second end of the second capacitor.

6. The bias circuit according to claim 2, further comprising:
a second bipolar transistor, wherein a power supply voltage is supplied to a collector of the second bipolar transistor, a control voltage is supplied to a base of the second bipolar transistor, and a second bias current or voltage is supplied from an emitter of the second bipolar transistor to the amplifier; and
a second capacitor,
wherein a first end of the second capacitor is connected to the emitter of the second bipolar transistor and the radio frequency signal is supplied to a second end of the second capacitor.

7. The bias circuit according to claim 3, further comprising:
a second bipolar transistor, wherein a power supply voltage is supplied to a collector of the second bipolar transistor, a control voltage is supplied to a base of the second bipolar transistor, and a second bias current or voltage is supplied from an emitter of the second bipolar transistor to the amplifier; and
a second capacitor,
wherein a first end of the second capacitor is connected to the emitter of the second bipolar transistor and the radio frequency signal is supplied to a second end of the second capacitor.

8. The bias circuit according to claim 4, further comprising:
a second bipolar transistor, wherein a power supply voltage is supplied to a collector of the second bipolar transistor, a control voltage is supplied to a base of the second bipolar transistor, and a second bias current or voltage is supplied from an emitter of the second bipolar transistor to the amplifier; and
a second capacitor,
wherein a first end of the second capacitor is connected to the emitter of the second bipolar transistor and the radio frequency signal is supplied to a second end of the second capacitor.

9. The bias circuit according to claim 1, further comprising:
a first resistor having a first end connected to the source of the FET and a second end connected to the amplifier; and
a second resistor having a first end connected to the source of the FET and a second end connected to the base of the first bipolar transistor.

10. The bias circuit according to claim 2, further comprising:
a first resistor having a first end connected to the source of the FET and a second end connected to the amplifier; and
a second resistor having a first end connected to the source of the FET and a second end connected to the base of the first bipolar transistor.

11. The bias circuit according to claim 3, further comprising:
a first resistor having a first end connected to the source of the FET and a second end connected to the amplifier; and
a second resistor having a first end connected to the source of the FET and a second end connected to the base of the first bipolar transistor.

12. The bias circuit according to claim 4, further comprising:
a first resistor having a first end connected to the source of the FET and a second end connected to the amplifier; and
a second resistor having a first end connected to the source of the FET and a second end connected to the base of the first bipolar transistor.

13. The bias circuit according to claim 5, further comprising:
a third resistor having a first end connected to the emitter of the second bipolar transistor and a second end connected to the amplifier.

14. The bias circuit according to claim 6, further comprising:
a third resistor having a first end connected to the emitter of the second bipolar transistor and a second end connected to the amplifier.

15. The bias circuit according to claim 7, further comprising:
a third resistor having a first end connected to the emitter of the second bipolar transistor and a second end connected to the amplifier.

16. The bias circuit according to claim 8, further comprising:
a third resistor having a first end connected to the emitter of the second bipolar transistor and a second end connected to the amplifier.
